(19) United States
(12) Patent Application Publication
(10) Pub. No.: US 2009/0088224 A1
(43) Pub. Date: Apr. 2, 2009

(54) ADAPTIVE VOLUME CONTROL

(75) Inventors: Thierry LE GALL, Guipavas (FR); Fabien OBER, Villeneuve Loubet (FR); Laurent LE FAUCHEUR, Antibes (FR)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/931,040

(22) Filed: Oct. 31, 2007

(30) Foreign Application Priority Data
Sep. 27, 2007 (EP) 07291156.3
Sep. 28, 2007 (EP) 07291179.5

(51) Int. Cl. H04B 1/38; H03G 3/32; H03G 5/16; H04M 1/00

(52) U.S. Cl. 455/570; 381/57; 379/388.03

(57) ABSTRACT

A system comprising processing logic and sound-capturing logic coupled to the processing logic. The sound-capturing logic provides a captured signal to the processing logic. The captured signal is associated with a property. Transceiver logic is coupled to the processing logic. The transceiver logic provides a received signal to the processing logic. The received signal is associated with a volume. Using a compression technique, the processing logic adjusts the volume in accordance with the property.

### CROSS-REFERENCE TO RELATED APPLICATION

The present application claims priority to EP Application No. 07291156.3, filed on Sep. 27, 2007, and EP Application No. 07291179.5, filed on Sep. 28, 2007, both of which are hereby incorporated herein by reference.

### BACKGROUND

Communication networks (e.g., mobile communication networks, plain-old-telephone-service (POTS) networks) facilitate communication between multiple communication devices (e.g., mobile communication devices, land-line telephones). Audio signals (such as speech data provided by a user) collected using one communication device may be transferred to and output by other communication devices. However, in addition to speech data, these audio signals unfortunately may include ambient noise data.

### SUMMARY

Accordingly, these are disclosed herein techniques for amplification of voice data in accordance with a volume level of the ambient noise data. An illustrative embodiment includes a system comprising processing logic and sound-capturing logic coupled to the processing logic. The sound-capturing logic provides a captured signal to the processing logic. The captured signal is associated with a property. Transceiver logic is coupled to the processing logic. The transceiver logic provides a received signal to the processing logic. The received signal is associated with a volume. Using a compression technique, the processing logic adjusts the volume in accordance with the property.

Another illustrative embodiment includes a mobile telephone comprising processing logic and transceiver logic coupled to the processing logic. The transceiver logic receives a first signal having a voice component. The telephone also comprises a microphone coupled to the processing logic, where the microphone receives a second signal having a noise component. The processing logic determines a magnitude of the noise component and, based on the magnitude, adjusts a volume of the voice component on a frame-by-frame basis.

Yet another illustrative embodiment includes a computer-readable medium comprising software code which, when executed by a processor, causes the processor to receive a first signal comprising a voice component, receive a second signal comprising a noise component and, using compression techniques, adjust a volume of the voice component in accordance with a volume of the noise component. The processor also outputs the volume-adjusted voice component.

### BRIEF DESCRIPTION OF THE DRAWINGS

For a detailed description of exemplary embodiments of the invention, reference will now be made to the accompanying drawings in which:

FIG. 1 shows an illustrative communication device implementing the technique disclosed herein, in accordance with various embodiments;

FIG. 2 shows illustrative circuit logic housed within the device of FIG. 1, in accordance with various embodiments;

FIG. 3 shows a conceptual block diagram illustrative of the technique disclosed herein, in accordance with preferred embodiments; and

FIG. 4 shows a flow diagram of an illustrative method implemented in accordance with various embodiments.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical or wireless connection. Thus, if a first device couples to a second device, that connection may be through a direct electrical or wireless connection, or through an indirect electrical or wireless connection via other devices and connections. The term “connection” refers to any path via which a signal may pass. For example, the term “connection” includes, without limitation, wires, traces and other types of electrical conductors, optical devices, wireless pathways, etc. Further, the term “or” is meant to be interpreted in an inclusive sense rather than in an exclusive sense. The term “property,” as used in the claims, generally refers to the volume of ambient noise captured by a communication device microphone, but also may refer to another property or properties of signals.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

The level of ambient, acoustic noise captured by the microphone of a communication device is indicative of the level of ambient noise actually present in the communication device's environment. High levels of ambient noise are indicative of noisy environments and low levels of ambient noise are indicative of quiet environments. In noisy environments, the communication device user may not be able to hear the voice of the person with whom the user is communicating. In quiet environments, the voice of the person communicating with the user may be too loud.

For example, person A (located in a quiet office) may be communicating with person B (located on a noisy street) by telephone. Although person A may be able to hear and understand person B's voice, person B may not be able to hear or understand person A's voice because of person B's noisy environment. Accordingly, disclosed herein are various embodiments of a technique by which a communication device adaptively adjusts output speech volume in accordance with the level of ambient noise associated with the communication device. In the above example, person B's communication device determines the amount of ambient noise associated with person B's environment. Based on this determination, person B's device adjusts the volume of person A's speech on received signals so that person B can hear person A's voice.

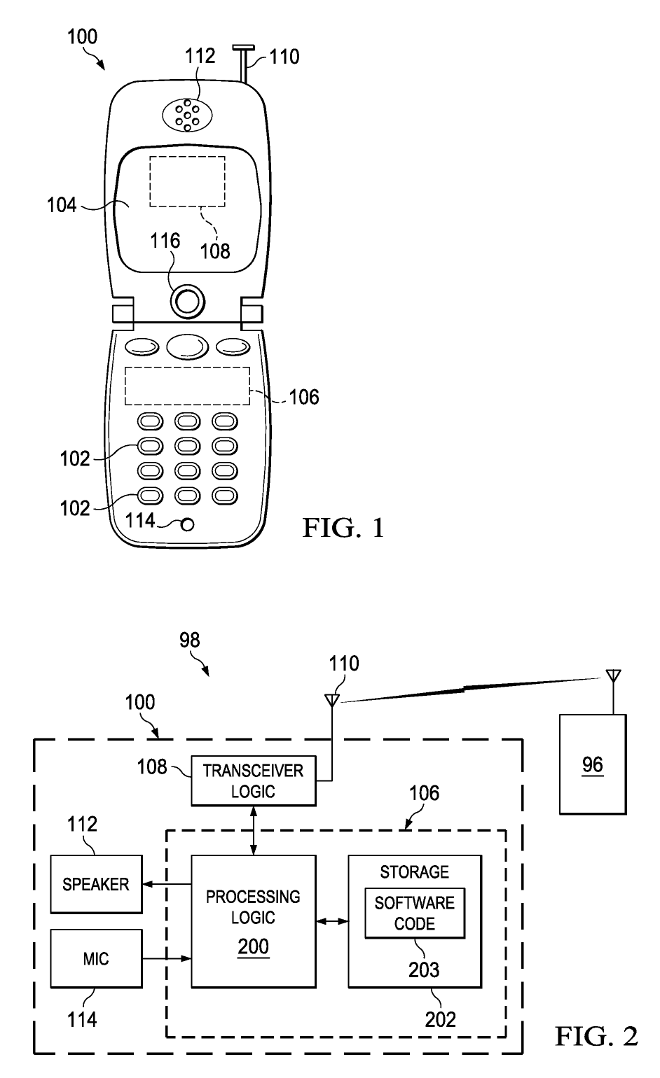

FIG. 1 shows an illustrative communication device 100 implementing the disclosed technique. The device 100 is shown as being a mobile phone, but in alternative embodiments, the device 100 may comprise any type of mobile communication device. For example, the device 100 may comprise a personal digital assistant (e.g., BLACKBERRY®, PALM®), a multimedia communication device (e.g., APPLE® iPHONE®) and/or any other kind of mobile electronic device, such as a personal notebook computer. Similarly, the device 100 also may comprise any type of non-mobile communication device, such as a desktop personal computer or a plain-old-telephone-service (POTS) based land-line telephone (including cordless phones). Voice-over-Internet-Protocol (VoIP) may be used in one or more of these embodiments. The device 100 may comprise either a battery-operated or a non-battery-operated device.

Still referring to FIG. 1, the device 100 comprises an integrated keypad 102, display 104 and transceiver logic 108 (e.g., in wireless devices, radio frequency circuitry such as BLUETOOTH®, and in non-wireless devices, generic transmit/receive logic). The display 104 may comprise any type of suitable display, such as a liquid crystal display (LCD). The device 100 also includes an electronics package 106 coupled to the keypad 102, display 104 and transceiver logic 108. The electronics package 106 contains various electronic components used by the device 100, including processing logic, storage logic, etc. The device 100 also comprises a speaker 112, used to output audible signals, and a microphone 114, used to receive audible signals. In some embodiments, the device 100 includes an imaging device or sensor (e.g., a camera) 116. The transceiver logic 108 may couple to an antenna 110 by which data transmissions are sent and received. The contents of the electronics package 106, which implement techniques in accordance with embodiments of the invention, are now described in detail with reference to FIG. 2.

FIG. 2 shows a network 98. The network 98 comprises a communication device 96 communicably coupled to the device 100. It should be understood that devices 96 and 100 may communicate with each other via an intervening telephone system including, for example, base stations. As previously mentioned, the device 100 comprises the electronics package 106. FIG. 2 shows circuit logic housed within, and coupled to, the electronics package 106. Specifically, FIG. 2 shows the electronics package 106 comprising processing logic 200 and a storage 202 comprising software code 203. The processing logic 200 couples to transceiver logic 108, antenna 110, microphone 114 and speaker 112. The storage 202 may comprise a processor (computer)-readable medium such as random access memory (RAM), volatile storage such as read-only memory (ROM), a hard drive, flash memory, etc. or combinations thereof. Although storage 202 is represented in FIG. 2 as being a single storage unit, in some embodiments, the storage 202 comprises a plurality of discrete storage units. When executed by the processing logic 200, the software code 203 causes the processing logic 200 to perform the technique disclosed herein.

The communication device 100 may communicate with one or more other communication devices via the transceiver logic 108 and the antenna 110. For example, the microphone 114 may capture audio signals (including speech signals and ambient noise signals) using the microphone 114. The microphone 114 converts the audio signals to electrical audio signals. The electrical audio signals are then modulated and transmitted to one or more other communication devices (e.g., device 96) using the processing logic 200, transceiver logic 108 and antenna 110. Similarly, the device 100 may receive modulated audio signals from other communication devices (e.g., device 96) using antenna 110 and transceiver logic 108. The received signals are converted into electrical audio signals which are output by the speaker 112 in the form of audible sound. The reproduced audible sound may comprise both speech signals and noise signals from another communication device.

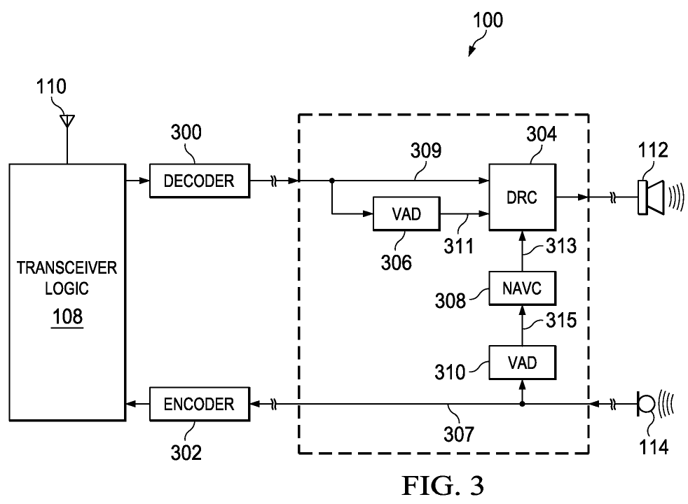

In accordance with various embodiments of the invention, when executed, the software code 203 causes the processing logic 200 to adaptively adjust the volume of the speech signals output by the speaker 112 so that the received speech signals are audible over the ambient noise associated with the device 100. More specifically, the processing logic 200 captures audio signals (i.e., including both speech signals and ambient noise signals) from the microphone 114. The logic 200 determines the volume (e.g., the magnitude) of the ambient noise associated with the device 100. Based on this determination, the logic 200 automatically increases or decreases the volume of the audio signals output by the speaker 112. The logic 200 preferably adjusts only the volume of the speech portion (and not the noise portion) of the audio signals output by the speaker 112. In this way, the device 100 adaptively adjusts the volume of output speech based on the level of ambient noise associated with the device 100. In some embodiments, properties of signals besides the volume or level of ambient noise may be used in lieu of the ambient noise volume. The manner by which the device 100 performs adaptive volume control is now described with reference to FIG. 3.

FIG. 3 shows a conceptual block diagram of the technique implemented via execution of the software code 203 by the processing logic 200 of FIG. 2. Specifically, FIG. 3 shows a speech decoder 300, a speech encoder 302, a Dynamic Range Compressor (DRC) 304, a Voice Activity Detector (VAD) 306, a Noise Adaptive Volume Control (NAVC) 308, a VAD 310, the speaker 112 and the microphone 114. In some embodiments, one or more of the components 300, 302, 304, 306, 308 and 310 comprises circuit logic. In other embodiments, one or more of the components 300, 302, 304, 306, 308 and 310 is implemented as part of the software code 203 of FIG. 2. In the context of such software-based embodiments, when one of these components is described herein as “performing” an activity, it is understood that the portion of the software code 203 corresponding to the component is being executed by the processor 200. Thus, it is actually the processor 200 that is performing the activity of the component being described.

As previously explained, the device 100 adaptively adjusts a volume of the speaker 112 in accordance with the level of ambient noise associated with the device 100. Accordingly, referring to FIGS. 2 and 3, the microphone 114 captures sound signals which comprise both speech signals (i.e., provided by a user) and ambient noise signals. The microphone 114 converts the audible sound signals into electrical audio signals comprising both speech and ambient noise. The electrical audio signals are provided to the encoder 302 and subsequently to the transceiver logic 108 for transmission to a destination communication device. The electrical audio signals also are provided to the VAD 310.

The VAD 310 distinguishes the noise from the speech so that it can determine the energy level of the noise. By “distinguish,” it is meant that the VAD 310 filters the received audio signal so that it can differentiate between the noise and the speech. The VAD 310 may distinguish between speech and noise using any suitable algorithm or technique. For example, the VAD 310 may detect a sudden rise in energy levels at a rate that exceeds a predetermined rate (e.g., 24 dB per second). Also, for example, the VAD 310 may detect harmonics in the lowest part of the frequency spectrum. Regardless, the VAD 310 provides this ambient noise energy level information to the NAVC 308 by way of a noise signal, as indicated by numeral 315.

The NAVC 308 receives the energy level information and uses the information to determine what amount of gain (e.g., volume increase), if any, should be applied to speech signals output via the speaker 112. Any number of suitable algorithm(s) may be utilized to make such a determination of the target gain level. In preferred embodiments, the NAVC 308 uses multiple predetermined thresholds (e.g., stored in the storage 202) in determining the gain that should be applied to the speech output by the speaker 112. Specifically, the NAVC 308 receives the energy level of the ambient noise via signal 315 and compares the energy level to a first threshold. If the energy level meets or does not exceed the first threshold, the NAVC 308 determines the target gain level to be “0,” because there is no need to increase the speech volume.

However, if the noise energy level exceeds the first threshold, the NAVC 308 determines by how much the energy level exceeds the first threshold. In this way, the NAVC 308 determines a difference between the first threshold and the energy level of the ambient noise associated with the device 100. The NAVC 308 determines a target gain level in accordance with this difference using any suitable technique. For example, the software code 203 may comprise a formula or algorithm that is used to determine a target gain level using the difference between the first threshold and the ambient noise level. Other techniques also may be used. For example, the storage 202 may comprise a preprogrammed data structure that associates various difference levels with corresponding target gain levels.

After determining a target gain level, the NAVC 308 compares the target gain level with a second threshold. The second threshold, possibly set by a manufacturer of the device 100, dictates the maximum desired target gain level. If the target gain level exceeds the second threshold, the device 100 adjusts the target gain level to be approximately the same as the second threshold. For example, if the NAVC 308 determines that a target gain level of “3” should be used, but the second threshold is “2,” the NAVC 308 adjusts the target gain level from “3” down to “2.” If the target gain level is less than or equal to the second threshold, the NAVC 308 preferably does not adjust the target gain level. After determining a target gain level, the NAVC 308 sends this target gain level to the DRC 304 as indicated by numeral 313. There is now described a technique by which audio signals received from another communication device are processed, followed by a description of how the target gain level is applied to the received audio signals before they are output on the speaker 112.

Another communication device (e.g., a mobile phone, a PDA, a land-line telephone) may be in communications with the device 100 via a network (not specifically shown). The device 100 receives modulated audio signals from the other communication device using the antenna 110 and the transceiver logic 108. The transceiver logic 108 converts the modulated audio signals into electrical audio signals. The decoder 300 decodes the received, electrical audio signals and provides them to the DRC 304 and the VAD 306.

Before the DRC 304 can apply the target gain level described above to the received audio signal, the DRC 304 must first determine which portion of the received audio signal comprises speech and which portion of the received audio signal comprises noise. As previously explained, it is preferable, although not required, to increase the volume of only the speech and not the noise.

The DRC 304 distinguishes between speech and noise on the received audio signal using information provided by the VAD 306. Specifically, like the VAD 310, the VAD 306 receives an audio signal (e.g., the audio signal from the decoder 300) and distinguishes between the speech portions of the signal and the noise portions of the signal. The VAD 306 may distinguish between these portions of the received audio signal using any suitable technique. After determining which portions of the received audio signal comprise noise and which portions comprise speech, the VAD 306 provides a noise signal to the DRC 304, as indicated by numeral 311, that is indicative of the acoustical noise content (e.g., volume) of the captured audio signal.

The DRC 304 increases the volume of speech received from the decoder 300 using both information from the VAD 306 (i.e., to determine which portions of the received audio signal contain speech) and the target gain level from the NAVC 308 (i.e., to determine by how much the speech volume should be increased). In preferred embodiments, the DRC 304 uses any of a variety of compression techniques (e.g., dynamic range compression) to increase the volume of the speech data. For example, if the target gain level is “2,” the DRC 304 may increase the volume of the speech data by a factor of 2 using dynamic range compression. The speech data component of the received audio signal is thus modified by the DRC 304. The modified audio signal may then be output by the speaker 112 in the form of audible sound. In this way, the volume of speech sound produced by the speaker 112 is adaptively and automatically adjusted in accordance with the level of ambient noise surrounding the device 100.

In preferred embodiments, the adaptive volume control process described above is performed on a frame-per-frame basis. For example, a stream of audio data received by the device 100 via antenna 110 and transceiver logic 108 may comprise a plurality of frames (e.g., 10 millisecond or 20 millisecond frames). These frames are provided to the DRC 304, as described above. In some embodiments, the NAVC 308 produces a single target gain level for each frame. In other embodiments, the NAVC 308 continuously produces target gain levels, and at the time the DRC 304 receives a frame, the DRC 304 uses the most recent target gain level provided by the NAVC 308. Regardless of the technique used, the DRC 304 uses the target gain level to adjust the speech data volume of each frame as described above. Similarly, the VAD 310 also may process the audio signals captured by the microphone 114 on a frame-by-frame basis.

Because the determination of the target gain level (i.e., using the NAVC 308, VAD 310 and noise data captured by the microphone 114) occurs on a substantially real-time basis, the DRC 304 is provided with a target gain level determined using the most recent ambient noise signal(s) available. Thus, there is minimal (or close to minimal) delay between the time the ambient noise data is captured by the microphone 114 and the time that the target gain level is applied to each frame of the received audio signal. Accordingly, the overall effect experienced by a user of the device 100 is that of real-time, adaptive volume control. Volume adjustments preferably are automatic or substantially automatic (e.g., performed with minimal or no undue human intervention).

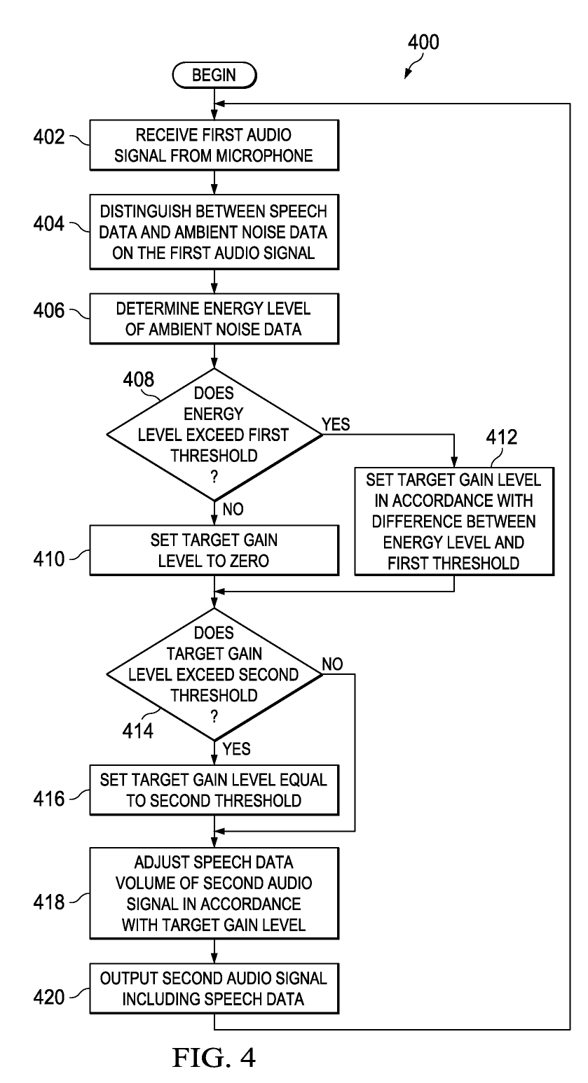

FIG. 4 shows a flow diagram of an illustrative method 400 implemented in accordance with various embodiments. The method 400 begins by receiving a first audio signal from the microphone (block 402). The method 400 continues by distinguishing between speech and ambient noise on the first audio signal (block 404). The method 400 comprises determining the energy level of the ambient noise (block 406). The method 400 also comprises determining whether the energy level exceeds a first threshold (block 408). If not, the method 400 comprises setting a target gain level to zero (block 410). If so, the method 400 comprises setting the target gain level in accordance with the difference between the energy level and the first threshold (block 412).

The method 400 then comprises determining whether the target gain level exceeds a second threshold (block 414). If so, the method 400 comprises setting the target gain level equal to the second threshold (block 416). Regardless, the method 400 then comprises adjusting the speech volume of the second audio signal in accordance with the target gain level (block 418). The second audio signal, including the volume-adjusted speech, is then output via a speaker (block 420).

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
processing logic;
sound-capturing logic coupled to the processing logic, the sound-capturing logic provides a captured audio signal to the processing logic, the captured signal having a property; and
transceiver logic coupled to the processing logic, the transceiver logic provides a received signal to the processing logic, the received signal associated with a volume;
wherein, using a compression technique, the processing logic adjusts said volume in accordance with said property.

2. The system of claim 1, wherein said compression technique comprises dynamic range compression (DRC).

3. The system of claim 1, wherein the received signal comprises a most-recently-captured signal from the sound-capturing logic.

4. The system of claim 1, wherein the processing logic compares an energy level of ambient noise associated with the system to a threshold, and wherein, based on said comparison, the processing logic determines an amount by which said volume is to be adjusted.

5. The system of claim 1, wherein the processing logic compares a threshold with an amount by which said volume is to be adjusted, and wherein the processing logic adjusts said amount based on said comparison.

6. The system of claim 1, wherein the volume comprises a volume of speech data contained in the received signal.

7. The system of claim 1, wherein said property comprises ambient noise volume associated with a communication device from which the received signal is received.

8. The system of claim 1, wherein the processing logic adjusts said volume of the received signal on a frame-by-frame basis.

9. The system of claim 1, wherein the system comprises a cellular telephone.

10. The system of claim 1, wherein the system comprises a land-line telephone.

11. The system of claim 1, wherein the processing logic automatically adjusts said volume.

12. A mobile telephone, comprising:
processing logic;
transceiver logic coupled to the processing logic, said transceiver logic receives a first signal having a voice component; and
a microphone coupled to the processing logic, said microphone receives a second signal having a noise component;
wherein the processing logic determines a magnitude of the noise component and, based on said magnitude, adjusts a volume of the voice component on a frame-by-frame basis.

13. The mobile telephone of claim 12, wherein the processing logic automatically adjusts said volume.

14. The mobile telephone of claim 12, wherein the processing logic adjusts said volume using a compression technique.

15. The mobile telephone of claim 14, wherein said compression technique comprises dynamic range compression (DRC).

16. The mobile telephone of claim 12, wherein said processing logic determines said magnitude using a most-recently-captured signal from the microphone.

17. A computer-readable medium comprising software code which, when executed by a processor, causes the processor to:
receive a first signal comprising a voice component;
receive a second signal comprising a noise component;
using compression techniques, adjust a volume of said voice component in accordance with a volume of the noise component; and
output said volume-adjusted voice component.

18. The computer-readable medium of claim 17, wherein the processor compares an energy level of ambient noise associated with the processor to a threshold, and wherein, based on said comparison, the processor determines a quantity by which said volume is to be adjusted.

19. The system of claim 17, wherein the processor compares a threshold with a quantity by which said volume is to be adjusted, and wherein the processor adjusts said quantity based on said comparison.

20. The system of claim 17, wherein the processor adjusts the volume of the voice component of the first signal on a frame-by-frame basis.
